(19) United States
(12) Patent Application Publication
(10) Pub. No.: US 2025/0140658 A1
(43) Pub. Date: May 1, 2025

(54) SEMICONDUCTOR DEVICE

(71) Applicant: FUJI ELECTRIC CO., LTD., Kawasaki-shi (JP)

(72) Inventors: Masanori TANAKA, Kawasaki-shi (JP); Takuya OGUCHI, Kawasaki-shi (JP)

(73) Assignee: FUJI ELECTRIC CO., LTD., Kawasaki-shi (JP)

(21) Appl. No.: 18/819,970

(22) Filed: Aug. 29, 2024

(30) Foreign Application Priority Data
Oct. 27, 2023 (JP) 2023-184365

(51) Int. Cl. H01L 23/495; H01L 23/00; H01L 23/31; H01L 25/065

(52) U.S. Cl. CPC H01L 23/49575; H01L 23/49551; H01L 24/48; H01L 25/0655; H01L 23/3107; H01L 2224/48108; H01L 2224/48137; H01L 2224/48175

(57) ABSTRACT

A semiconductor device includes a semiconductor chip, a main current lead frame having a main die pad on which the semiconductor chip is disposed, a control element connected to the semiconductor chip via a first control wiring, and a control lead frame having a control die pad on which the control element is disposed. The control lead frame includes a first frame having the control die pad and a second frame connected to the control element via a second control wiring. The first frame further includes a bent portion that is bent such that the control die pad is positioned lower than the second frame in a thickness direction (Z direction) of the semiconductor chip.

### CROSS-REFERENCE TO RELATED APPLICATION

This application is based upon and claims the benefit of priority to Japanese Patent Application No. 2023-184365, filed on Oct. 27, 2023, the entire contents of which are incorporated herein by reference.

### BACKGROUND OF THE INVENTION

### 1. Technical Field

The present invention relates to a semiconductor device including a main current lead frame having a main die pad on which a semiconductor chip is disposed and a control lead frame having a control die pad on which a control element is disposed.

### 2. Description of the Related Art

As a semiconductor device used in a power conversion device, there is a semiconductor device in which a control die pad of a control lead frame on which a control element is disposed is located above a main die pad of a main current lead frame on which a semiconductor chip is disposed. In such a semiconductor device, a semiconductor chip, a control element, a lead frame, and the like are connected to each other by wiring and sealed with a sealing resin (see, for example, JP 2014-99547 A, JP 2016-129257 A, JP 2019-87565 A, JP 2008-186889 A, and JP 2000-196002 A).

### SUMMARY OF THE INVENTION

In the control lead frame, for example, in order to suppress deformation of a control wiring at the time of resin molding by reducing the difference in height between the control die pad and the main die pad, it is preferable to provide a bent portion that makes the height of the control die pad lower than the height of the extending portion from the sealing resin. However, since the width of each separated frame of the control lead frame is narrow, when the control lead frame is bent, the positional accuracy of each frame deteriorates.

An object of the present invention is to provide a semiconductor device capable of improving positional accuracy of a control lead frame.

A semiconductor device according to one aspect includes a semiconductor chip; a main current lead frame having a main die pad on which the semiconductor chip is disposed; a control element connected to the semiconductor chip via a first control wiring; and a control lead frame having a control die pad on which the control element is disposed, in which the control lead frame includes a first frame having the control die pad and a second frame connected to the control element via a second control wiring, and the first frame further includes a bent portion that is bent such that the control die pad is positioned lower than the second frame in a thickness direction of the semiconductor chip.

According to the above aspect, the positional accuracy of the control lead frame can be improved.

### BRIEF DESCRIPTION OF THE DRAWINGS

FIG. 1 is a plan view illustrating a semiconductor device according to an embodiment;

FIG. 2 is a right side view illustrating an internal structure of the semiconductor device according to the embodiment;

FIG. 3 is a cross-sectional view taken along line III-III of FIG. 1;

FIG. 4 is a plan view for explaining a flow rate (s/L) corresponding to a loop height of a first control wiring in the embodiment; and

FIG. 5 is a graph showing a relationship between a loop height and a flow rate (deformation rate) of control wiring in the embodiment.

### DETAILED DESCRIPTION

Hereinafter, a semiconductor device according to an embodiment of the present invention will be described in detail with reference to the drawings. Note that each axis of X, Y, and Z in each of the drawings to be referred to is illustrated for the purpose of defining a direction in the exemplified semiconductor device 1. The X, Y, and Z axes are orthogonal to each other and form a right-handed system. In the following description, a Z direction which is a thickness direction of semiconductor chips 11 to 14 is defined as a vertical direction. These directions are terms used for convenience of description, and the correspondence relationship with each of the XYZ directions may change depending on the attachment posture of the semiconductor device 1. For example, in the present specification, a surface facing the positive side in the Z direction (+Z direction) in the member constituting the semiconductor device 1 is referred to as an upper surface, a surface facing the negative side in the Z direction (−Z direction) is referred to as a lower surface, a surface facing the negative side in the Y direction (−Y direction) is referred to as a front surface, and four surfaces facing both sides in the X direction and both sides in the Y direction including the front surface are referred to as side surfaces. In addition, in the present specification, a plan view means a case where the upper surface of the semiconductor device 1 is viewed from the negative side in the Z direction.

Furthermore, an aspect ratio and a size relationship between the members in each drawing are merely schematically represented, and do not necessarily coincide with a relationship in the semiconductor device 1 or the like actually manufactured. In addition, the shapes of the same members may be different between different drawings.

In the following description, as an example of the semiconductor device 1 according to the present embodiment, a device applied to a power conversion device such as an inverter device of an industrial or in-vehicle motor will be described. Therefore, in the following description, detailed description of the same or similar configuration, function, operation, assembly method, and the like as those of the known semiconductor device will be omitted.

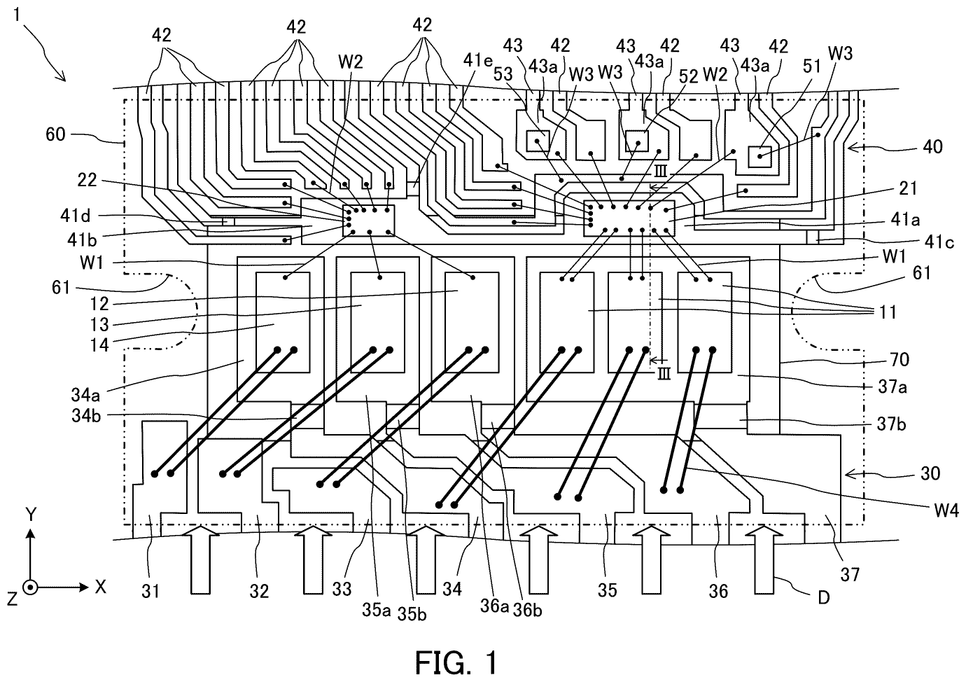

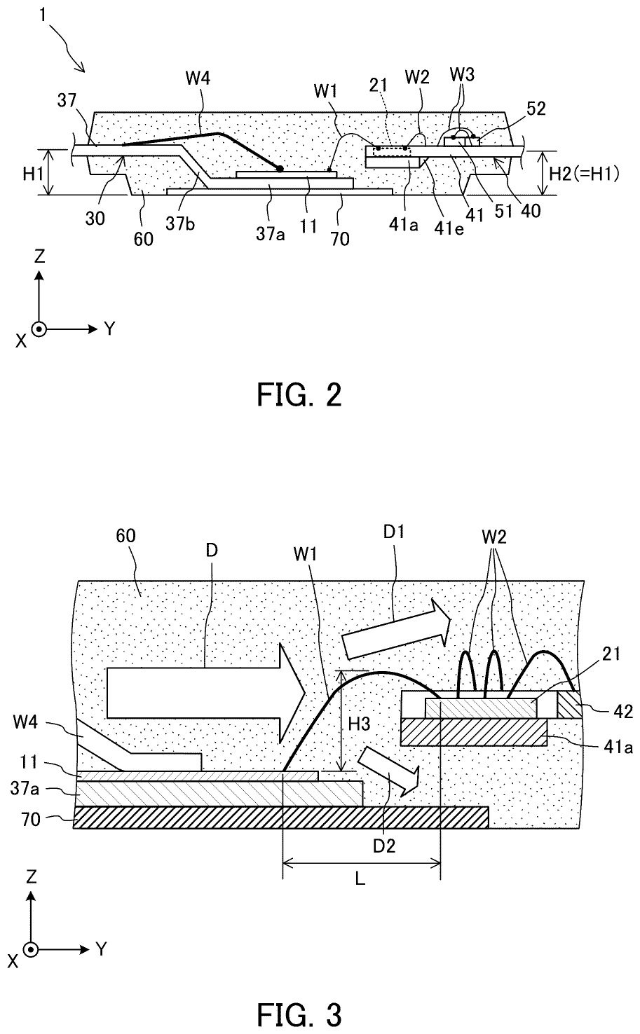

FIG. 1 is a plan view illustrating a semiconductor device 1. FIG. 2 is a right side view illustrating an internal structure of the semiconductor device 1. FIG. 3 is a cross-sectional view taken along line III-III of FIG. 1. In FIG. 1, a sealing resin 60 is indicated by a two-dot chain line (imaginary line).

As illustrated in FIG. 1, the semiconductor device 1 includes a plurality of semiconductor chips 11 to 14, a plurality of control elements 21 and 22, a main current lead frame 30, a control lead frame 40, a plurality of electronic components 51 to 53, a sealing resin 60, and an insulating sheet 70. In addition, the semiconductor device 1 includes a plurality of first control wirings W1, a plurality of second control wirings W2, a plurality of third control wirings W3, and a plurality of main current wirings W4.

Each of the semiconductor chips 11 to 14 includes, for example, a reverse conducting (RC)-IGBT element in which an insulated gate bipolar transistor (IGBT) element which is a switching element and a diode element such as a free wheeling diode (FWD) element connected in antiparallel to the switching element are integrated. Instead of each of the semiconductor chips 11 to 14, a semiconductor chip having a switching element and a semiconductor chip having a diode element may be individually provided.

A first main electrode (not illustrated) is provided on the lower surface of each of the semiconductor chips 11 to 14. A second main electrode and a control electrode (gate electrode) (not illustrated) are provided on the upper surface of each of the semiconductor chips 11 to 14. When the switching element of each of the semiconductor chips 11 to 14 is an IGBT element, the first main electrode on the lower surface is called a collector electrode, and the second main electrode on the upper surface is called an emitter electrode.

For example, six semiconductor chips 11 to 14 including three semiconductor chips 11 and semiconductor chips 12 to 14 are arranged side by side in the X direction. The three semiconductor chips 11 constituting an upper arm are all arranged on a single main die pad 37a of a main current lead frame 37 described later. The three semiconductor chips 12 to 14 constituting a lower arm are arranged on main die pads 34a, 35a, and 36a of different main current lead frames 34 to 36. The first main electrodes on the lower surfaces of the semiconductor chips 11 to 14 are preferably bonded to the main die pads 34a, 35a, 36a, and 37a with conductive bonding materials such as solder, respectively.

Each of the second main electrode and the control electrode on the upper surface of each of the three semiconductor chips 11 constituting the upper arm is connected to the common control element 21 via the first control wiring W1. In addition, the three semiconductor chips 11 are connected to the main current lead frames 34 to 36 different from the main current lead frame 37 having the main die pad 37a on which these semiconductor chips 11 are arranged via the main current wirings W4, respectively, on the upper surface. Since the connection in the present specification includes an electrical connection, the connection includes not only direct bonding (fixing) but also indirect bonding (fixing) via another member.

The control electrode on the upper surface of each of the semiconductor chips 12 to 14 constituting the lower arm is connected to a common control element 22 via the first control wiring W1. In addition, the semiconductor chips 12 to 14 are connected to the main current lead frames 31 to 33 via the main current wiring W4 on the upper surface, respectively.

The control element 21 is, for example, a high voltage integrated circuit (HVIC), and the control element 22 is, for example, a low voltage integrated circuit (LVIC). The control elements 21 and 22 desirably have a sensor function of detecting environmental information such as temperature and a protection circuit function of operating based on a detection result of the environmental information.

The control elements 21 and 22 are arranged side by side in the X direction on control die pads 41a and 41b provided on a single first frame 41 of the control lead frame 40. The lower surfaces of the control elements 21 and 22 are preferably bonded to the control die pads 41a and 41b with a conductive bonding material such as solder, respectively.

As described above, the control element 21 is connected to the three semiconductor chips 11 via two first control wirings W1, respectively, and the control element 22 is connected to the semiconductor chips 12 to 14 via one first control wiring W1, respectively. As an example, the electrode on the upper surface of the control element 21 is connected to seven second frames 42 and component die pads 43a of three third frames 43 of the control lead frame 40 via the second control wiring W2, respectively. The electrode on the upper surface of the control element 22 is connected to the seven second frames 42 via the second control wiring W2, respectively.

The main current lead frame 30 has seven frames (also referred to as main current lead frames 31 to 37, respectively). Each of the main current lead frames 31 to 37 functions as an output circuit unit. The main current lead frames 31 to 37 are arranged side by side in the X direction in the order of reference signs 31 to 37 from the main current lead frame 31 positioned on the most negative side in the X direction to the main current lead frame 37 positioned on the most positive side in the X direction.

The main current lead frames 34 to 37 respectively having the main die pads 34a, 35a, 36a, and 37a extend from the main die pads 34a to 37a to the negative side in the Y direction (an example of the first direction) away from the control die pads 41a and 41b, thereby extending from the sealing resin 60 to function as main current terminals. The main current lead frames 34 to 37 extend toward the negative side in the Y direction while being bent toward the positive side in the X direction from the main die pads 34a to 37a, respectively. Also, in this case, it can be said that the main current lead frames extend toward the negative side in the Y direction. The main current lead frames 31 to 33 also extend toward the negative side in the Y direction, extend from the sealing resin 60, and function as main current terminals.

As shown in FIG. 2, the main current lead frames 34 to 37 (only the main current lead frame 37 is shown in FIG. 2) have bent portions 34b, 35b, 36b, and 37b that are bent downward in the Z direction (the thickness direction of the semiconductor chip 11) so that the main die pads 34a to 37a are in contact with the upper surface of the insulating sheet 70 described later.

As described above, the control lead frame 40 illustrated in FIG. 1 includes the first frame 41, the plurality of second frames 42, and the three third frames 43. Each of the frames 41 to 43 functions as a control circuit unit. The first frame 41 has control die pads 41a and 41b positioned at a distance from each other in the X direction, extends to both sides in the X direction so as to be away from each other from the control die pads 41a and 41b, and then extends to the positive side in the Y direction (an example of a second direction opposite to the first direction) away from the main die pads 34a to 37a. The three third frames 43 have component die pads 43a on which electronic components 51, 52, and 53 are disposed, respectively.

The first frame 41 has three bent portions 41c, 41d, and 41e that are bent such that the control die pads 41a and 41b are positioned lower than the second frame 42 and the third frame 43 (component die pad 43a) in the Z direction. The two bent portions 41c and 41d are provided on both sides in the X direction (an example of a third direction side and a fourth direction side orthogonal to the first direction and the second direction and opposite to each other) with respect to the control die pads 41a and 41b in the first frame 41. The control die pads 41a and 41b are positioned at the same height in the Z direction by being sandwiched between the bent portions 41c and 41d. Even in this case, the bent portions 41c and 41d may be positioned to be shifted to the positive side in the Y direction with respect to the control die pads 41a and 41b. The bent portion 41e is provided on the positive side in the Y direction with respect to the control die pads 41a and 41b. The height at which the bent portions 41c, 41d, and 41e make the control die pads 41a and 41b lower than the extending portion of the first frame 41 from the sealing resin 60 may be equal to or less than the plate thickness of the first frame 41.

The control lead frame 40 (all of the first frame 41, the second frame 42, and the third frame 43) extends from the sealing resin 60 toward the positive side in the Y direction and functions as a control terminal. As shown in FIG. 2, with reference to the lower surface of the sealing resin 60, the height H2 at which the control lead frame 40 extends from the sealing resin 60 is desirably the same height in the Z direction as the height H1 at which the main current lead frame 30 (main current lead frames 31 to 37) extends from the sealing resin 60. Since the height may slightly vary even if the same height is intended due to the influence of tolerance or the like, for example, even if there is a difference in the heights H1 and H2 about the thickness of the main current lead frame 30 or the control lead frame 40, it can be said that the heights are the same.

The main current lead frame 30 and the control lead frame 40 are formed, for example, by performing processing such as etching or punching on one metal flat plate having a wiring pattern. As a material of the main current lead frame 30 and the control lead frame 40, for example, a metal material such as a copper material, a copper alloy-based material, an aluminum alloy-based material, or an iron alloy-based material is desirable.

The bent portions 34b to 37b of the main current lead frame 30 and the bent portions 41c to 41e of the control lead frame 40 are formed by press working, for example. The bent portions 34b to 37b and the bent portions 41c to 41e may be bent while changing the extending direction, and may be curved without being angular.

Each of the electronic components 51 to 53 is, for example, a boot strap diode. Each of the electronic components 51 to 53 may be another component such as a passive element such as a thermistor, a capacitor, or a resistor. Each of the electronic components 51 to 53 is preferably bonded to the component die pad 43a of the third frame 43 with a conductive bonding material such as solder. Each of the electronic components 51 to 53 is connected to the second frame 42 via the third control wiring W3.

The sealing resin 60 has, for example, a rectangular parallelepiped shape longer in the X direction and the Y direction than in the Z direction, and seals the semiconductor chips 11 to 14, the control elements 21 and 22, the electronic components 51 to 53, the first to third control wirings W1 to W3, the main current wiring W4, and the like. As illustrated in FIG. 1, each of a side surface on the positive side in the X direction and a side surface on the negative side in the X direction of the sealing resin 60 is provided with a recess 61 having a U-shape (semicircular shape) in plan view. These recesses 61 can be referred to as grooves penetrating the sealing resin 60 in the Z direction. For example, the recess 61 is used to insert a bolt for attaching the semiconductor device 1 to a cooler such as a cooling fin disposed below the semiconductor device 1. The sealing resin 60 is, for example, a thermosetting resin such as an epoxy resin, and is desirably molded by transfer molding.

As described above, from the sealing resin 60, the main current lead frame 30 extends toward the negative side in the Y direction, and the control lead frame 40 extends toward the positive side in the Y direction. The sealing resin 60 is injected from an injection gate into a space between upper and lower molds (not illustrated) at the same height in the Z direction as the height from which the main current lead frames 31 to 37 extend, for example. As indicated by arrows indicating a resin injection direction D in FIG. 1, the sealing resin 60 is injected from six positions between the main current lead frames 31 to 37. That is, the sealing resin 60 is injected from the side surface (front surface) from which the main current lead frames 31 to 37 extend. This side surface is a surface on the negative side in the Y direction of the sealing resin 60, but may not be formed of a single plane, and may be formed of a plurality of planes or a curved surface.

The injection portion of the sealing resin 60 can be identified as an injection portion (trace indicating that the sealing resin 60 has been injected) by being cut after the injected sealing resin 60 is cured. The entire semiconductor device 1 except the sealing resin 60 is preferably inserted into the mold, and the main current lead frame 30 and the control lead frame 40 preferably extend from the sealing resin 60. That is, it is preferable that before injection of the sealing resin 60 (before insertion into the mold), the semiconductor chips 11 to 14, the control elements 21 and 22, and the electronic components 51 to 53 are arranged on the main current lead frame 30 or the control lead frame 40, wiring of the first to third control wirings W1 to W3 and the main current wiring W4 is performed, and the insulating sheet 70 is attached to the lower surfaces of the main die pads 34a to 37a of the main current lead frames 34 to 37. The insulating sheet 70 may be bonded to the lower surfaces of the main die pads 34a to 37a by being thermally cured together with the sealing resin 60 in a semi-cured state before injection of the sealing resin 60.

As illustrated in FIG. 2, the lower surface of the insulating sheet 70 is flush with the lower surface of the sealing resin 60, and the lower surface is exposed to the outside of the sealing resin 60. For example, the insulating sheet 70 is preferably formed in a rectangular shape in plan view larger on both sides in the X direction and on both sides in the Y direction than the four main die pads 34a to 37a to be attached. Since the control die pad 41a (control lead frame 40) is positioned above the main die pads 34a to 37a in the Z direction, the insulating sheet 70 does not contact the control lead frame 40.

The insulating sheet 70 is preferably formed of a material having not only the insulating properties of the main die pads 34a to 37a but also heat dissipation properties in order to conduct heat generated from the semiconductor chips 11 to 14 to a cooler disposed below the insulating sheet 70. Therefore, the insulating sheet 70 can also be referred to as a heat dissipation sheet. Furthermore, the insulating sheet 70 can also be referred to as an insulating plate, an insulating substrate, a heat dissipation plate, a heat dissipation substrate, or the like. The insulating sheet 70 is made of, for example, an epoxy resin.

The wire diameters of the first to third control wirings W1 to W3 are, for example, about 15 to 50 μm, and are thinner than the wire diameter of the main current wiring W4, for example, about 1/10. Therefore, the rigidity of the first to third control wirings W1 to W3 is much lower than that of the main current wiring W4, and the first to third control wirings W1 to W3 are easily deformed by the resin flow at the time of transfer molding of the sealing resin 60. When the first to third control wirings W1 to W3 are deformed in this manner, a short circuit between different potentials, a decrease in bonding strength (open) due to deformation, and the like may occur.

In particular, as illustrated in FIG. 3, since the first control wiring W1 connecting the semiconductor chip 11 and the control element 21 (the same applies to the semiconductor chips 12 to 14 and the control element 22) is separated in the height direction (Z direction) by the semiconductor chip 11 being positioned lower than the control element 21 in the Z direction, a loop height H3 of the first control wiring W1 increases, and the effective wiring length increases. Therefore, since the first control wiring W1 receives a strong load, the first control wiring W1 is particularly easily deformed, and the manufacturability and the quality are easily deteriorated. In particular, since the sealing resin 60 injected in the resin injection direction D at the time of transfer molding is branched into an upper flow direction D1 of the control element 21 in the Z direction and a lower flow direction D2 of the control element 21 in the Z direction, the height of the control element 21 in the Z direction increases, and as the loop height H3 increases, the sealing resin 60 easily flows in the lower flow direction D2. Therefore, the first control wiring W1 extending so as to cross the flow direction D2 is easily deformed.

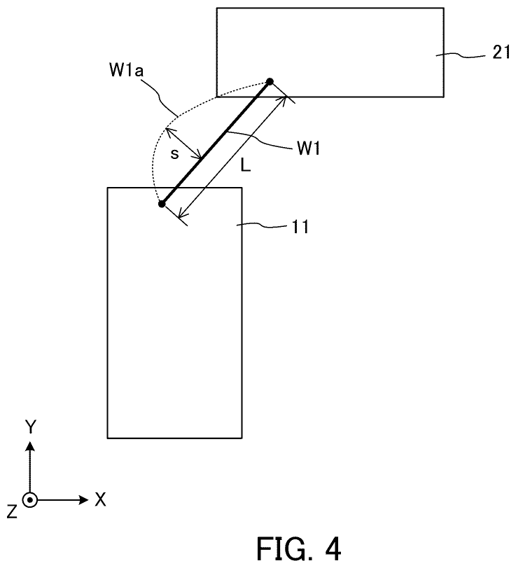

Here, as illustrated in FIG. 4, the first control wiring W1 having the length L in plan view is deformed by flowing toward the positive side in the Y direction due to the resin flow at the time of transfer molding of the sealing resin 60, and the deformed first control wiring W1 is defined as a deformed first control wiring W1a (illustrated by a broken line). The flow rate s/L [%] represented by the flow amount s, which is the maximum length between the first control wiring W1 and the first control wiring W1a in the direction orthogonal to the first control wiring W1 in plan view, and the length L varies depending on the loop height H3 of the first control wiring W1 illustrated in FIG. 3.

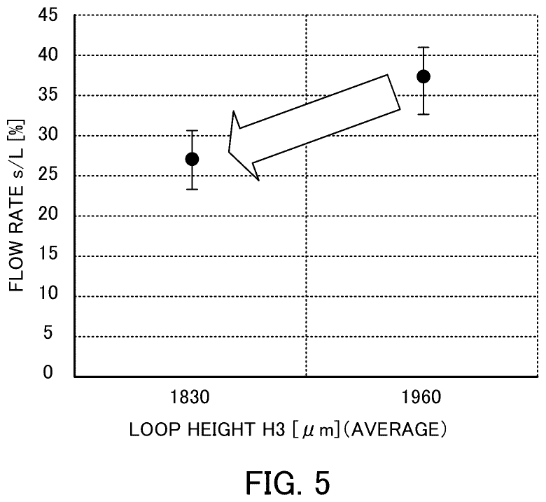

As shown in FIG. 5, the flow rate s/L, which was about 37 [%] on average when the loop height H3 was 1960 [μm], decreased to about 27 [%] on average when the loop height H3 was 1830 [μm]. As the loop height H3 is lowered in this manner, deformation of the first control wiring W1 can be suppressed. Therefore, as described above, when the first frame 41 of the control lead frame 40 has the bent portions 41c, 41d, and 41e, the control die pads 41a and 41b are positioned downward in the Z direction so as to approach the heights of the main die pads 34a to 37a of the main current lead frame 30, which is effective from the viewpoint of reducing the loop height H3 and suppressing deformation of the first control wiring W1. In addition, by suppressing the wiring deformation of the first control wiring W1 and the like, it is possible to avoid thickening of the wiring. Therefore, it is also possible to prevent an increase in size and cost of the semiconductor chip 11 having many bond pads and the control elements 21 and 22, a decrease in reliability of the semiconductor device 1 (for example, peeling due to an increase in stress of the sealing resin 60), and the like. When the control die pads 41a and 41b are lowered to the heights of the main die pads 34a to 37a in the Z direction, the cost increases due to an increase in size of the insulating sheet 70, wiring (for example, ultrasonic bonding) of the first to third control wirings W1 to W3 becomes difficult, and bending processing of the control lead frame 40 becomes difficult.

As an example, the control lead frame 40 includes many frames 41 to 43 separated from each other, such as 1 first frame 41, 14 second frames 42, and 3 third frames 43. Therefore, each of the frames 41 to 43 has a narrow width orthogonal to the extending direction in plan view.

Therefore, when all the frames 41 to 43 are bent, the positional accuracy of each of the frames 41 to 43 is deteriorated, and for example, the distance between the frames is shortened, or the size is increased to secure the distance between the frames.

Therefore, while the first frame 41 has the bent portions 41c, 41d, and 41e, it is desirable that the second frame 42 and the third frame 43 do not have a bent portion at least inside the sealing resin 60.

In addition, the control elements 21 and 22 disposed on the control die pads 41a and 41b of the first frame 41 are connected to the second frame 42 and the third frame 43 via the second control wiring W2. Therefore, by lowering the heights of the control die pads 41a and 41b of the first frame 41 in the Z direction and bringing the heights of the upper surfaces of the control elements 21 and 22 close to the heights of the upper surfaces of the second frame 42 and the third frame 43, similarly to the loop height H3 of the first control wiring W1 described above, the loop height of the second control wiring W2 can also be lowered, and eventually, deformation of the second control wiring W2 can also be suppressed. As described above, in the control lead frame 40, it is effective to reduce the heights of the control die pads 41a and 41b in the Z direction.

In the present embodiment described above, the semiconductor device 1 includes the semiconductor chips 11 to 14, the main current lead frames 34 to 37 respectively having the main die pads 34a to 37a on which the semiconductor chips 11 to 14 are disposed, the control elements 21 and 22 connected to the semiconductor chips 11 to 14 via the first control wiring W1, and the control lead frame 40 having the control die pads 41a and 41b on which the control elements 21 and 22 are respectively disposed. The control lead frame 40 includes the first frame 41 having the control die pads 41a and 41b, and the second frame 42 connected to the control elements 21 and 22 via the second control wiring W2. The first frame 41 further includes bent portions 41c, 41d, and 41e that are bent such that the control die pads 41a and 41b are positioned lower than the second frame 42 in the thickness direction (Z direction) of the semiconductor chips 11 to 14.

As described above, by providing the bent portions 41c to 41e such that the control die pads 41a and 41b of the first frame 41 are positioned lower than the second frame 42 in the Z direction, the number of frames to be bent can be reduced as compared with an aspect in which not only the control die pad 41a but also the second frame 42 is bent downward in the Z direction. In particular, the number of second frames 42 connected to the control elements 21 and 22 via the second control wirings W2 is large, and each of the second frames 42 has a narrow width and is densely arranged. Therefore, if these second frames 42 are also bent downward in the Z direction, the positional accuracy of the second frame 42 and eventually the positional accuracy of the control lead frame 40 deteriorate. Therefore, according to the present embodiment, the positional accuracy of the control lead frame 40 can be improved. In addition, by improving the positional accuracy of the control lead frame 40, it is also possible to suppress short-circuiting due to a short distance between two adjacent second frames 42, between the second frame 42 and the first frame 41, or the like, and to suppress an increase in size of the control lead frame 40 and eventually the semiconductor device 1 in order to secure the distance.

Furthermore, since the control die pads 41a and 41b are positioned lower than the second frame 42 in the Z direction, the heights of the upper surfaces of the control elements 21 and 22 are brought close to the height of the upper surface of the second frame 42, whereby the loop height of the second control wiring W2 connecting the control elements 21 and 22 and the second frame 42 can be reduced. This makes it possible to suppress deformation of the second control wiring W2 due to resin flow with a simple configuration at the time of transfer molding of the sealing resin 60 or the like. In addition, since the heights of the control elements 21 and 22 can be brought close to the heights of the semiconductor chips 11 to 14, the detection accuracy of the environmental information such as the temperature detected by the control elements 21 and 22 can be improved. In the present embodiment, the control die pads 41a and 41b of the control lead frame 40 are positioned above the main die pads 34a to 37a of the main current lead frame 30 in the Z direction.

Therefore, by bending the first frame 41 so that the control die pads 41a and 41b are positioned lower than the second frame 42 in the Z direction as described above, it is possible to reduce the difference in height between the control elements 21 and 22 and the semiconductor chips 11 to 14, and eventually reduce the loop height H3 of the first control wiring W1 connecting the control elements 21 and 22 and the semiconductor chips 11 to 14. In addition, at the time of transfer molding of the sealing resin 60 or the like, the sealing resin 60 is less likely to flow below the first frame 41 (the flow velocity of the sealing resin 60 decreases), and deformation of the first control wiring W1 due to resin flow can be suppressed with a simple configuration.

In the present embodiment, the main current lead frames 34 to 37 extend from the main die pad 34a toward the negative side in the Y direction (an example of the first direction) away from the control die pads 41a and 41b. The first frame 41 extends from the control die pads 41a and 41b toward the positive side in the Y direction (an example of a second direction opposite to the first direction). The bent portions 41c and 41d are provided on both sides in the X direction (an example of a third direction side and a fourth direction side orthogonal to the first direction and the second direction and opposite to each other) with respect to the control die pads 41a and 41b in the first frame 41.

As a result, the region extending in the X direction between the control die pads 41a and 41b and the bent portions 41c and 41d is also positioned lower than the second frame 42, so that the sealing resin 60 hardly flows below the first frame 41. Therefore, deformation of the first control wiring W1 can be suppressed with a simple configuration.

In the present embodiment, the semiconductor device 1 further includes the sealing resin 60 that seals at least the semiconductor chips 11 to 14 and the control elements 21 and 22, and the main current lead frame 30 and the control lead frame 40 extend from the sealing resin 60 at the same heights H1 and H2 in the Z direction.

This facilitates processing when the main current lead frame 30 and the control lead frame 40 are processed from one metal flat plate, and improves the usability of the control terminals of the main current lead frame 30 and the control lead frame 40 extending from the sealing resin 60.

In the present exemplary embodiment, the sealing resin 60 is injected from a side surface (for example, the front surface on the negative side in the Y direction) from which the main current lead frame 30 extends.

As a result, the first to third control wirings W1 to W3 having lower rigidity than the main current wiring W4 are positioned on the downstream side in the resin injection direction D of the sealing resin 60, so that deformation of the first to third control wirings W1 to W3 can be suppressed.

Furthermore, in the present embodiment, the semiconductor device 1 includes the plurality of control elements 21 and 22, the first frame 41 includes the plurality of control die pads 41a and 41b in which the control elements 21 and 22 are arranged, respectively, and the plurality of control die pads 41a and 41b are positioned at the same height in the Z direction.

As a result, as compared with an aspect in which only one of the control die pads 41a and 41b is positioned lower than the second frame 42 in the Z direction, the sealing resin 60 is less likely to flow in the flow direction D2 intersecting the first control wiring W1 connecting the semiconductor chips 11 to 14 and the control elements 21 and 22, and deformation of the first control wiring W1 can be suppressed with a simple configuration.

In the present embodiment, in the control lead frame 40, the electronic components 51, 52, and 53 connected to the second frame 42 via the third control wiring W3 are arranged on the component die pad 43a of the third frame 43. The control die pads 41a and 41b are positioned lower than the second frame 42 and the component die pad 43a in the Z direction.

As a result, the number of frames to be bent of the control lead frame 40 can be reduced as compared with the aspect in which the third frame 43 is bent downward in the Z direction. Therefore, since the positional accuracy of the third frame 43 can also be improved, the positional accuracy of the control lead frame 40 can be further improved. In addition, it is also possible to suppress a short circuit due to a short distance between the second frame 42 and the third frame 43 or the like, and to suppress an increase in size of the semiconductor device 1 in order to secure a distance.

The semiconductor device of the present invention is not limited to the semiconductor device 1 according to the present embodiment, and may be variously changed, replaced, and modified in a range without departing from the spirit of the technical idea. In addition, if the technical idea can be realized in another manner by the progress of the technology or another derived technology, the technology may be implemented by using the method. Therefore, the claims cover all implementations that may be included within the scope of the technical idea.

For example, the control die pads 41a and 41b of the control lead frame 40 may be positioned at the same height or lower than the main die pads 34a to 37a of the main current lead frame 30 in the Z direction. The positions of the bent portions 41c to 41e of the control lead frame 40 may be other positions as long as at least one of the control die pads 41a and 41b can be bent to be positioned lower than the second frame 42 in the Z direction. The height H1 in the Z direction at which the main current lead frame 30 extends from the sealing resin 60 may be different from the height H2 in the Z direction at which the control lead frame 40 extends from the sealing resin 60. The position where the sealing resin 60 is injected is not limited to the side surface (front surface) of the sealing resin 60 from which the main current lead frames 31 to 37 extend. The plurality of control die pads 41a and 41b of the control lead frame 40 may be provided at different heights in the Z direction. Further, the control die pads 41a and 41b only need to be positioned lower than the second frame 42 in the Z direction, and may be positioned at the same height as or above the third frame 43 (for example, a case where the third frame 43 has a bent portion so that the component die pad 43a is positioned lower than the second frame 42 in the Z direction) in the Z direction.

Hereinafter, some inventions described in the specification and drawings of the present application will be additionally described.

### Supplementary note 1

A semiconductor device comprising:
a semiconductor chip;
a main current lead frame having a main die pad on which the semiconductor chip is disposed;
a control element connected to the semiconductor chip via a first control wiring; and
a control lead frame having a control die pad on which the control element is disposed, in which
the control lead frame includes a first frame having the control die pad and a second frame connected to the control element via a second control wiring, and
the first frame further includes a bent portion that is bent such that the control die pad is positioned lower than the second frame in a thickness direction of the semiconductor chip.

### Supplementary note 2

The semiconductor device according to supplementary note 1, in which
the control die pad is positioned above the main die pad in the thickness direction.

### Supplementary note 3

The semiconductor device according to supplementary note 1 or 2, in which
the main current lead frame extends in a first direction away from the main die pad with respect to the control die pad,
the first frame extends from the control die pad in a second direction opposite to the first direction, and
the bent portion is provided on a third direction side and a fourth direction side that are orthogonal to the first direction and the second direction and are opposite to each other with respect to the control die pad in the first frame.

### Supplementary note 4

The semiconductor device according to any one of supplementary notes 1 to 3, further comprising a sealing resin that seals at least the semiconductor chip and the control element, in which the main current lead frame and the control lead frame extend from the sealing resin at the same height in the thickness direction.

### Supplementary note 5

The semiconductor device according to any one of supplementary notes 1 to 3, further comprising a sealing resin that seals at least the semiconductor chip and the control element, in which
the sealing resin is injected from a side surface from which the main current lead frame extends.

### Supplementary note 6

The semiconductor device according to any one of supplementary notes 1 to 5, further comprising a plurality of the control elements, in which
the first frame includes a plurality of the control die pads in each of which the control element is disposed, and
the plurality of control die pads are positioned at the same height in the thickness direction.

### Supplementary Note 7

The semiconductor device according to any one of supplementary notes 1 to 6, in which
the control lead frame further includes a third frame having a component die pad on which an electronic component connected to the second frame via a third control wiring is disposed, and
the control die pad is positioned lower than the second frame and the component die pad in the thickness direction.

### INDUSTRIAL APPLICABILITY

As described above, the present invention has an effect of improving the positional accuracy of the control lead frame, and is particularly useful for an industrial or electrical inverter device.

What is claimed is:

1. A semiconductor device, comprising:
a semiconductor chip;
a main current lead frame having a main die pad on which the semiconductor chip is disposed;
a control element connected to the semiconductor chip via a first control wiring; and
a control lead frame having a control die pad on which the control element is disposed, wherein
the control lead frame includes a first frame having the control die pad and a second frame connected to the control element via a second control wiring, and
the first frame further includes a bent portion that is bent such that the control die pad is positioned lower than the second frame in a thickness direction of the semiconductor chip.

2. The semiconductor device according to claim 1, wherein
the control die pad is positioned above the main die pad in the thickness direction.

3. The semiconductor device according to claim 1, wherein
the main current lead frame extends in a first direction away from the main die pad with respect to the control die pad,
the first frame extends from the control die pad in a second direction opposite to the first direction, and
the bent portion includes two bent portions, respectively connected to respective ones of two opposing sides of the control die pad of the first frame, the two opposing sides being opposite to each other in a direction orthogonal to the first direction and the second direction.

4. The semiconductor device according to claim 1, further comprising a sealing resin that seals at least the semiconductor chip and the control element, wherein
the main current lead frame and the control lead frame both extend from the sealing resin to an outside of the sealing resin at the same height in the thickness direction.

5. The semiconductor device according to claim 1, further comprising a sealing resin that seals at least the semiconductor chip and the control element, wherein
one or more traces indicating that the sealing resin has been injected are located at a side surface of the sealing resin from which the main current lead frame extends.

6. The semiconductor device according to claim 1, wherein
the control element is provided in plurality,
the control die pad is provided in plurality in the first frame and each of the control elements is disposed on a respective one of the plurality of control die pads, and
the plurality of control die pads are positioned at the same height in the thickness direction.

7. The semiconductor device according to claim 1, wherein
the control lead frame further includes a third frame having a component die pad on which an electronic component connected to the second frame via a third control wiring is disposed, and
the control die pad is positioned lower than the second frame and the component die pad in the thickness direction.
